(19) United States
(12) Patent Application Publication
(10) Pub. No.: US 2026/0216808 A1
(43) Pub. Date: Jul. 30, 2026

(54) JOINING SYSTEM AND JIG

(71) Applicant: Nippon Avionics Co., Ltd., Yokokama-shi (JP)

(72) Inventor: Shungo NISHIHARA, Yokohama-shi (JP)

(21) Appl. No.: 19/630,122

(22) Filed: Mar. 26, 2026

(30) Foreign Application Priority Data
Mar. 28, 2024 (JP) 2025-055587

(51) Int. Cl. B23K 3/08; B23K 1/06; H10W 72/00

(52) U.S. Cl. CPC B23K 3/087; B23K 1/06; H10W 72/07141

(57) ABSTRACT

A joining system includes a jig (20). A jig (20) includes a jig body (21) including a plurality of holding holes (22) each configured to hold a corresponding one of a plurality of workpieces (W), and a lid (25) configured to, when disposed on the jig body (21), cover the plurality of holding holes (22). A heater (30) heats the jig (20). An ultrasonic vibration applying device (80) applies ultrasonic vibration to the jig (20) during the joining, thereby applying the ultrasonic vibration to the workpieces (W) via the jig (20).

### TECHNICAL FIELD

The present disclosure relates to a joining system and a jig.

### BACKGROUND

As disclosed in Patent Literature 1 (JP 2010-56188 A), there is known a joining apparatus that joins a first component and a second component disposed above the first component using a joining material (solder in Patent Literature 1).

In joining using a joining material, good joining quality may not be obtained due to occurrence of inconveniences such as voids in the joining material, oxidation of the joining material, deformation of a workpiece, cracks, misalignment of the second component, or non-uniform heating among a plurality of workpieces when the plurality of workpieces are joined collectively.

### SUMMARY

It is an object of the present disclosure, in joining using a joining material, to make at least one of the above-described inconveniences less likely to occur and to obtain good joining quality.

To solve the above-described problem, according to the present disclosure, there is provided a joining system comprising: a jig including a jig body including a plurality of holding holes each configured to hold a corresponding one of a plurality of workpieces, each of the plurality of workpieces including a first component, a second component disposed above the first component, and a joining material disposed between the first component and the second component, and a lid configured to, when disposed on the jig body, cover the plurality of holding holes; a heater configured to heat the jig such that each of the plurality of workpieces is heated to effect joining of the first component and the second component with the heated joining material; and an ultrasonic vibration applying device configured to apply ultrasonic vibration to the jig during the joining, thereby applying the ultrasonic vibration to the workpieces via the jig.

According to the present disclosure, there is provided a jig comprising: a jig body including a plurality of holding holes each configured to hold a corresponding one of a plurality of workpieces, each of the plurality of workpieces including a first component, a second component disposed above the first component, and a joining material disposed between the first component and the second component; and a lid configured to, when disposed on the jig body, cover the plurality of holding holes.

According to the present disclosure, in joining using a joining material, at least one of the above-described inconveniences can be made less likely to occur, and good joining quality can be obtained.

### BRIEF DESCRIPTION OF THE DRAWINGS

FIG. 1 is a view illustrating a configuration of a joining system according to an embodiment. FIG. 2 is an exploded perspective view of a jig. FIG. 3 is a plan view illustrating a relationship between a jig body and a gas supply path of a lid. FIG. 4 is a cross-sectional view taken along line A-A of FIG. 3. FIG. 5 is a flowchart of a joining process. FIG. 6 is a plan view illustrating a relationship between a jig body and a gas supply path of a lid according to a modification. FIG. 7 is a perspective view of a jig body according to a modification. FIG. 8 is a plan view of a jig body according to a modification.

### EMBODIMENTS

Hereinafter, an embodiment of the present disclosure will be described with reference to the drawings. Note that the up-down direction, the front-back direction, and the left-right direction, which are orthogonal to one another and are defined in the drawings, are not intended to indicate an orientation of the joining system 10. For example, the up-down direction may or may not coincide with the top-bottom direction. In the drawings, among a plurality of identical elements, only some of the elements may be denoted by reference numerals. In the cross-sectional view of FIG. 4, internal configurations appearing in the section are omitted, and hatching is applied. A plan view means a view seen from above.

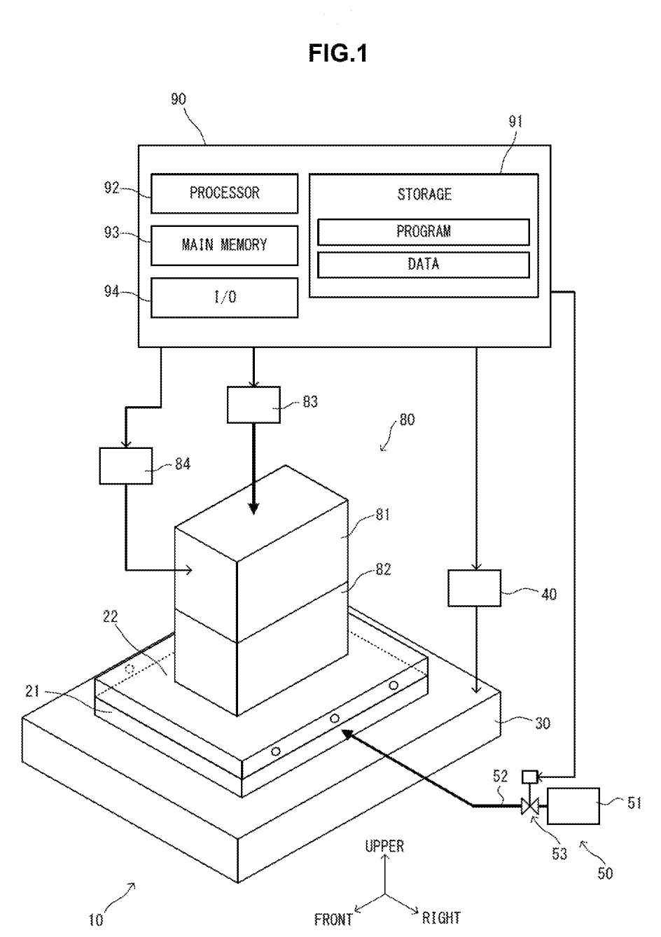

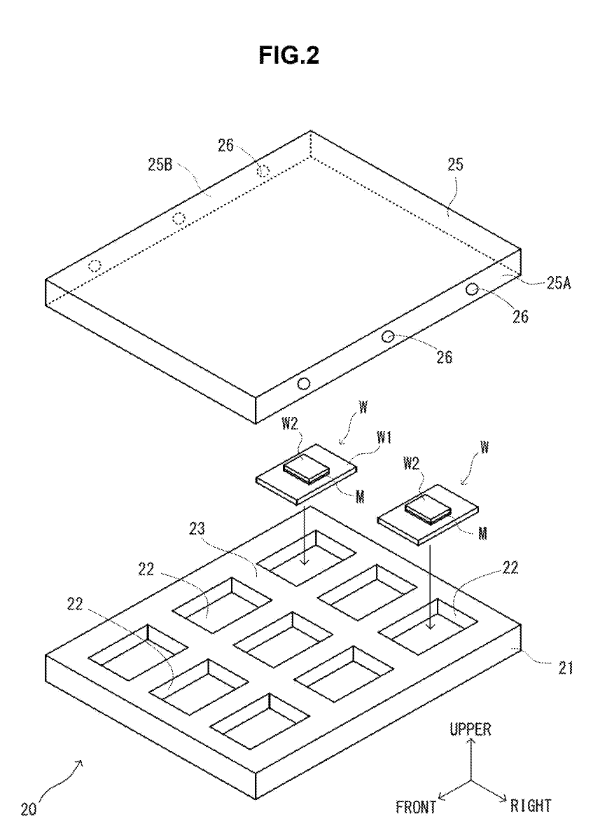

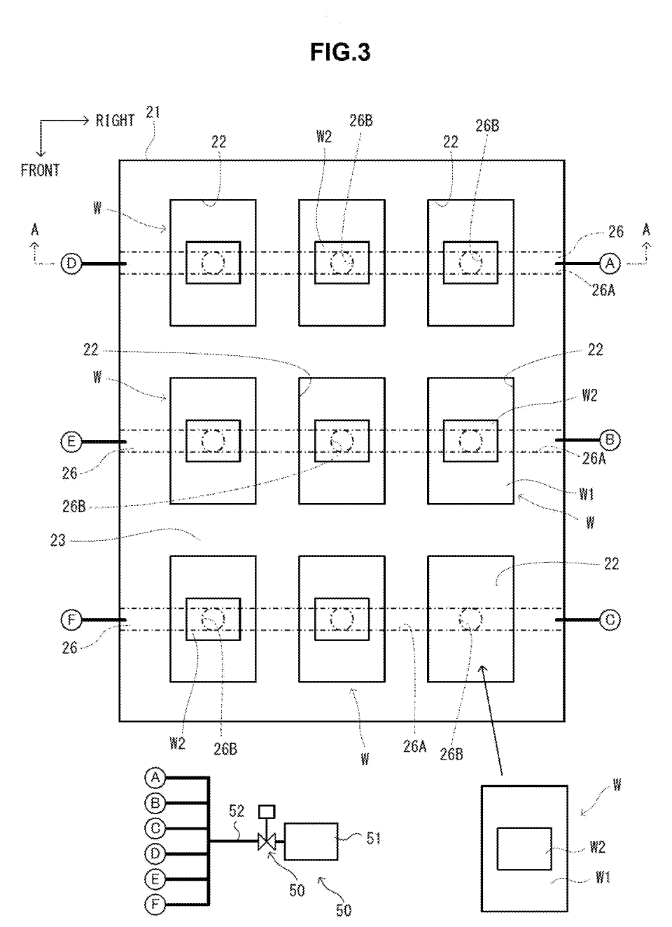

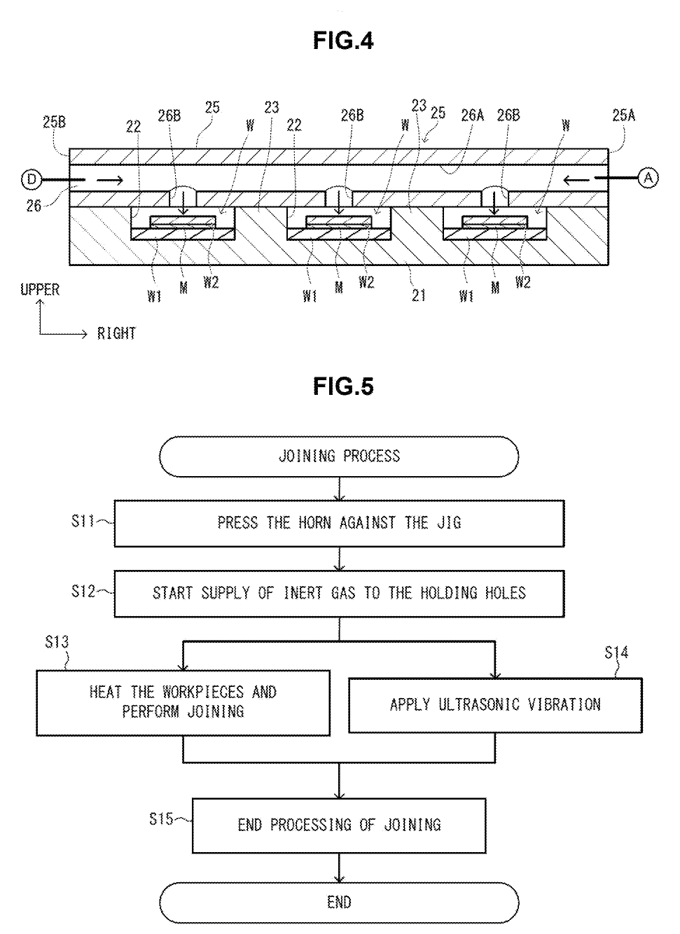

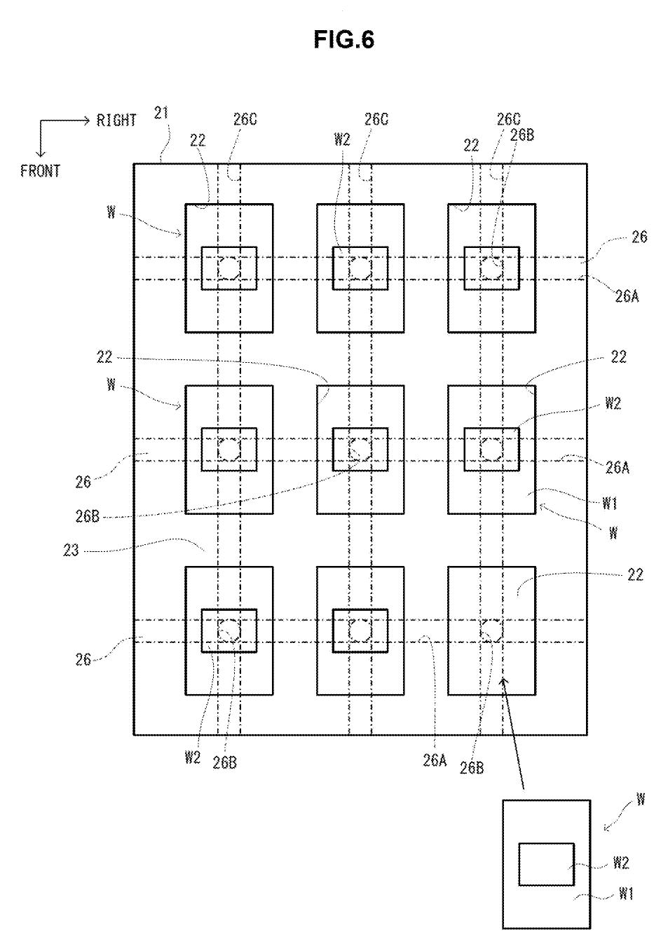

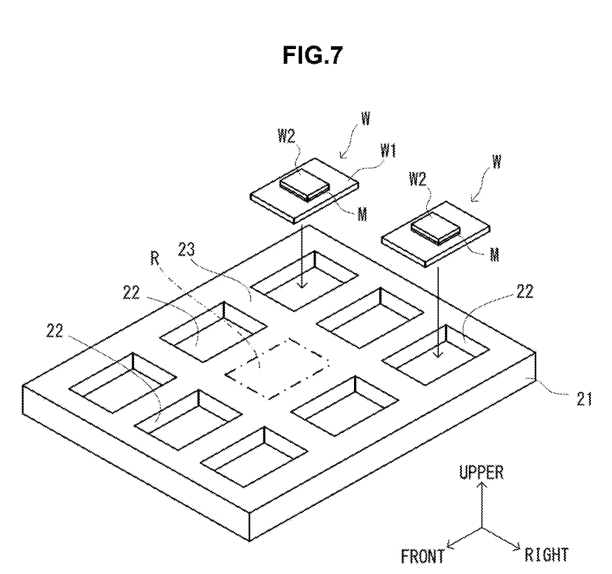

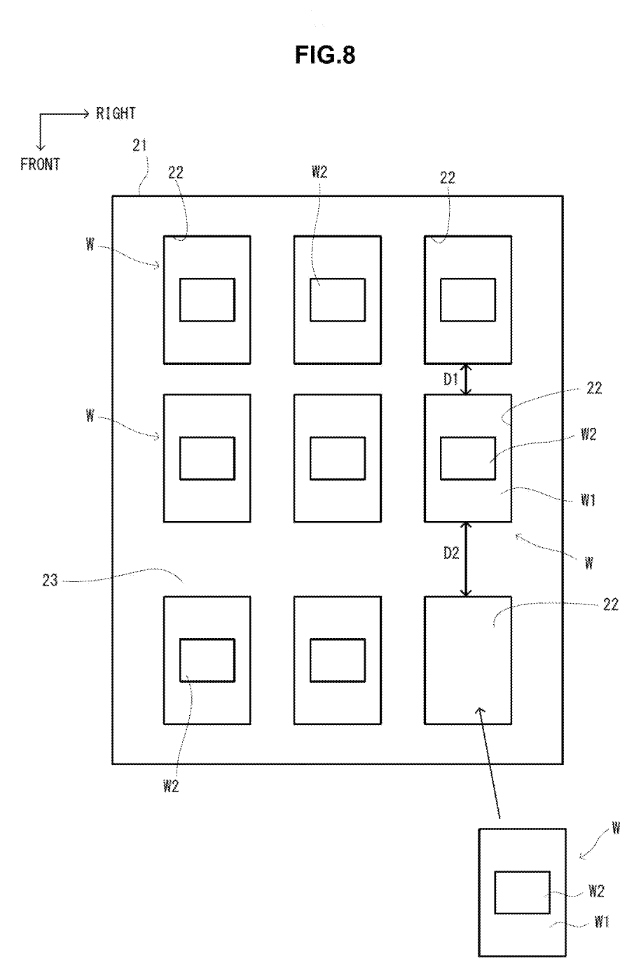

As shown in FIGS. 1 to 4, the joining system 10 according to this embodiment includes a jig 20, a heater 30, a power supply circuit 40, a gas supply device 50, an ultrasonic vibration applying device 80 (hereinafter also simply referred to as a device 80), and a controller 90.

As shown in FIGS. 2 to 4, in the joining system 10, a plurality of workpieces W are held by the jig 20. Each workpiece W includes a component W1, a component W2 disposed above the component W1, and a joining material M interposed therebetween. The joining system 10 heats the jig 20 to thereby collectively heat the respective workpieces W, and thereby joins the component W1 and the component W2 of each workpiece W with the heated joining material M. The joining material M is made of any one of a brazing material, solder, a sintering material, a thermoplastic resin, and a thermosetting resin. Each of the thermoplastic resin and the thermosetting resin includes a resin to which a specific function such as conductivity is imparted by mixing another material such as metal particles. The joining material M made of the brazing material, solder, or thermoplastic resin once melts or softens when heated and, after heating ends, solidifies, thereby joining the component W1 and the component W2. The joining material M made of the sintering material joins the component W1 and the component W2 by being sintered by heating. The thermosetting resin joins the component W1 and the component W2 by being cured by heating. The component W1 is, for example, a substrate. The component W2 is, for example, an IC (Integrated Circuit) chip. The joining material M may be configured as a plurality of bumps that respectively connect a plurality of terminals of the IC chip to a plurality of terminals of the substrate.

The jig 20 includes a partitioned tray-shaped jig body 21 that holds the plurality of workpieces W, and a plate-shaped lid 25 superposed on an upper surface of the jig body 21.

The jig body 21 includes a plurality of holding holes 22 (here, 3 × 3 = 9 holding holes) arranged in a matrix along the front-back direction and the left-right direction, and respectively accommodating and holding the plurality of workpieces W. Each holding hole 22 is a bottomed hole. Although only two workpieces W are shown in FIG. 2, as shown in FIG. 3 and the like, one workpiece W is accommodated and held in one holding hole 22. The jig body 21 includes a grid-like partition wall 23 partitioning the holding holes 22. An inner side surface of each holding hole 22 defined by the partition wall 23 has a shape (here, a rectangular shape in plan view) complementary to the shape of the component W1 of the workpiece W, and thereby positions the workpiece W. The inner side surface and bottom surface of the holding hole 22 may each have complementary irregularities matching the shape of the workpiece W, and the workpiece W may be positioned by the irregularities. The jig body 21 holds each of the plurality of workpieces W in a positioned state.

The lid 25 is disposed on the jig body 21 so as to be superposed thereon from above, and covers and closes the plurality of holding holes 22 of the jig body 21 from above. Each holding hole 22 is formed with a depth such that the workpiece W held therein does not contact the lid 25.

A gas supply path 26 through which gas supplied from the gas supply device 50 passes is provided in the lid 25. The gas supply path 26 includes three linear gas flow paths 26A and nine communication paths 26B. Each gas flow path 26A extends in the left-right direction. Each gas flow path 26A need only extend in the left-right direction, and may meander instead of extending linearly. Each gas flow path 26A has one end open at a side surface 25A of the lid 25 and the other end open at a side surface 25B of the lid 25 opposite to the side surface 25A. Each communication path 26B extends in the up-down direction and branches from one of the three gas flow paths 26A. Each communication path 26B communicates with a corresponding one of the holding holes 22. In plan view, the nine communication paths 26B are respectively arranged at positions overlapping the nine holding holes 22. Each communication path 26B is open at a lower surface of the lid 25. The opening position of each communication path 26B at the lower surface of the lid 25 faces, in the up-down direction, the component W2 of the workpiece W held in the holding hole 22 communicating with the communication path 26B.

The heater 30 shown in FIG. 1 heats the jig body 21 from below by generating heat due to Joule heat produced by a heating current supplied from the power supply circuit 40 including an inverter circuit and the like. By heating the jig body 21, the workpieces W are also heated. The heater 30 also functions as a stage that supports the workpieces W from below. The power supply circuit 40 controls, under control of the controller 90, a current value of the heating current supplied to the heater 30.

The gas supply device 50 includes a gas cylinder 51, a gas pipe 52, and a flow control valve 53. The gas cylinder 51 stores an inert gas such as nitrogen gas, argon gas, or neon gas. As shown in FIG. 3, the gas pipe 52 extends from the gas cylinder 51, branches into six, and is connected to both ends of each of the three gas flow paths 26A, in other words, to six openings formed in the side surfaces 25A and 25B. With this configuration, the inert gas from the gas cylinder 51 is supplied through the gas pipe 52 to the respective gas flow paths 26A from both left and right ends. Thereafter, the inert gas is supplied to each holding hole 22 through the respective communication path 26B. The inert gas supplied from the communication path 26B to the holding hole 22 impinges on the component W2 facing the opening of the communication path 26B at the lower surface of the lid 25 (see FIG. 4). As a result, the inert gas presses the component W2 downward (toward the component W1). The flow control valve 53 is disposed midway in a portion of the gas pipe 52 before the gas pipe 52 branches into six, and controls a flow rate of the inert gas flowing through the gas pipe 52. The controller 90 controls an amount of the inert gas supplied to each holding hole 22 by controlling an opening degree of the flow control valve 53.

The device 80 shown in FIG. 1 applies ultrasonic vibration to the workpieces W during joining. The device 80 includes an ultrasonic transducer (hereinafter also simply referred to as a transducer) 81, an ultrasonic horn (hereinafter also simply referred to as a horn) 82, a drive device 83, and a power supply circuit 84. The transducer 81 is constituted by, for example, a Langevin-type transducer, and vibrates in response to high-frequency electric power from the power supply circuit 84 to generate ultrasonic vibration. The horn 82 is fixed to the transducer 81. The drive device 83 is constituted by a linear motor, a ball screw mechanism, or the like. The drive device 83 moves the transducer 81 and the horn 82 downward, and presses a distal end (lower end) of the horn 82 against the upper surface of the lid 25. During this pressing, the transducer 81 generates ultrasonic vibration. The generated ultrasonic vibration is amplified by the horn 82 and applied to the lid 25. The ultrasonic vibration applied to the lid 25 is transmitted to the workpieces W via the jig body 21. The controller 90 controls operation of the device 80, specifically, operation of the drive device 83 and vibration of the transducer 81 (more specifically, operation of the power supply circuit 84).

The controller 90 is constituted by various computers, and includes nonvolatile storage 91 storing programs and the like, and a processor 92 that executes the programs stored in the storage 91. The storage 91 also stores data used in the processing described below. The processor 92 includes one or more CPUs (Central Processing Units) and the like. The controller 90 further includes a main memory 93 that provides a work area for the processor 92, and an I/O (Input/Output) 94 that relays electrical signals transmitted and received between the processor 92 and an exterior of the controller 90. The I/O 94 may include a circuit that converts a control signal from the processor 92 from digital to analog and supplies the converted signal to a control target.

During joining, the controller 90 (more specifically, the processor 92; the same applies hereinafter) performs joining processing shown in FIG. 5. At a start of the processing shown in FIG. 5, the jig 20 holding the plurality of workpieces W in the holding holes 22 is assumed to be disposed on the heater 30.

In the joining processing, first, the controller 90 controls the drive device 83 of the device 80 to move the transducer 81 and the horn 82 downward and press the lower end of the horn 82 against the upper surface of the lid 25 of the jig 20 (step S11). As a result, the horn 82 presses the lid 25 against the jig body 21.

Thereafter, the controller 90 operates the gas supply device 50 to start supply of the inert gas to each holding hole 22 (step S12). Because the inert gas impinges on the component W2 of the workpiece W, the component W2 of the workpiece W is pressed downward, and the possibility of misalignment of the component W2 when ultrasonic vibration is applied, as described later, is reduced. In addition, because the holding hole 22 is filled with the inert gas, oxidation of the joining material M is suppressed. Air originally present in the holding hole 22 may be expelled to an exterior of the jig 20 by the inert gas through an exhaust path (not shown). The exhaust path may, for example, pass through an inside of the jig body 21, or may be a gap between the jig body 21 and the lid 25. In order to maintain gas pressure in the holding hole 22 at a predetermined gas pressure higher than atmospheric pressure, the exhaust path may include a release valve that releases gas in the holding hole 22 to an exterior of the jig 20 when the gas pressure in the holding hole 22 exceeds the predetermined gas pressure. When the gas pressure in the holding hole 22 becomes the predetermined gas pressure higher than atmospheric pressure, movement of the component W2 can be suppressed by the high gas pressure in the holding hole 22.

Thereafter, the controller 90 controls the power supply circuit 40 to heat the workpieces W via the jig 20 by the heater 30 and perform joining (step S13). Heating is executed in accordance with a preset temperature profile (a temperature profile for realizing a heating temperature according to a material of the joining material M). At this time, the controller 90 may perform feedback control of the power supply circuit 40 based on a temperature of the jig 20 (in particular, the jig body 21) measured by a radiation thermometer (not shown), or may monitor a temperature change of the jig 20 in real time with a thermal imaging camera (not shown) and control the power supply circuit 40 based on a monitoring result.

In parallel with step S13, the controller 90 further operates the device 80 during a predetermined period during heating (in particular, a period during which the joining material M melts or sinters) to apply ultrasonic vibration to the jig 20 (lid 25) (step S14). The ultrasonic vibration is transmitted to the joining material M through the jig 20. The ultrasonic vibration promotes removal of voids from the joining material M during melting or sintering, thereby reducing a residual amount of voids in the joining material M after joining. If the gas pressure in the holding hole 22 is excessively high, removal of voids may be hindered. In such a case, the predetermined gas pressure is preferably a gas pressure that can ensure removal of voids.

After completion of steps S13 and S14, the controller 90 performs end processing of joining (step S15). The end processing includes controlling the drive device 83 of the device 80 to move the transducer 81 and the horn 82 upward and release the horn 82 from pressing against the upper surface of the lid 25.

As described above, the joining system 10 according to this embodiment includes the jig 20 including the jig body 21 having the plurality of holding holes 22 that respectively hold the plurality of workpieces W, and the lid 25 that is disposed on the jig body 21 and covers the plurality of holding holes 22. Further, the joining system 10 includes the heater 30 that heats the jig 20 to heat each of the plurality of workpieces W, thereby joining the component W1 and the component W2 of each workpiece W with the heated joining material M, and the ultrasonic vibration applying device 80 that applies

ultrasonic vibration to the jig 20 during the joining, thereby applying the ultrasonic vibration to the workpieces W via the jig 20. With such a configuration, voids are reduced by application of ultrasonic vibration. Further, conventionally, in application of ultrasonic vibration, the workpiece W has been sandwiched in the up-down direction between a horn and a heater tool. However, in such joining, the workpiece W, particularly the joining material M, is likely to be deformed or cracks are likely to occur due to pressurization from the up-down direction. According to the above configuration, the ultrasonic vibration is transmitted to the workpieces W via the jig 20 without sandwiching the workpieces W in the up-down direction. Therefore, the above deformation and cracks are less likely to occur. As described above, according to the above configuration, in joining using the joining material M, it is possible to make at least one of inconveniences such as voids in the joining material M, deformation of the workpieces W, and cracks less likely to occur, and thereby obtain good joining quality. In this embodiment, the plurality of workpieces W can be processed at once by using the jig 20. Note that making an inconvenience less likely to occur includes, for example, reducing an amount of occurrence of the inconvenience, such as reducing an amount of voids. The same applies to other inconveniences.

Further, in this embodiment, the heater 30 supports the jig body 21 from below and heats the jig body 21, and the ultrasonic vibration applying device 80 includes the ultrasonic transducer 81 and the ultrasonic horn 82 connected to the ultrasonic transducer 81, and applies ultrasonic vibration to the lid 25 in a state in which the ultrasonic horn 82 is pressed against the lid 25 from above. As a modification, the lid 25 may be heated and ultrasonic vibration may be applied to the jig body 21. However, according to the configuration of this embodiment, since the jig body 21 holding the workpieces W is heated, the lid 25 does not intervene in the heating, and therefore heating efficiency of the workpieces W is improved. Further, since the ultrasonic horn 82 is pressed against the lid 25 from above, efficiency of transmission of ultrasonic vibration from the lid 25 to the jig body 21 is also ensured.

Note that the lid 25 according to this embodiment is preferably formed of an ultrasonic conductive material having a heat-insulating effect so that heat from the jig body 21 is not transmitted to the horn 82. Further, only a portion of the lid 25 in contact with the horn 82 and/or a portion of the lid 25 in contact with the jig body 21 may be formed of an ultrasonic conductive material having a heat-insulating effect. Alternatively, an ultrasonic conductive material having a heat-insulating effect may be interposed between the lid 25 and the horn 82 and/or between the lid 25 and the jig body 21.

In this embodiment, the joining system 10 further includes the gas supply device 50 that supplies inert gas to each of the holding holes 22 during the joining. Further, the lid 25 includes the gas supply path 26 configured to cause the inert gas from the gas supply device 50 to impinge from above on the component W2 of each of the plurality of workpieces W. As a result, the component W2 is pressed downward by the inert gas, and therefore movement of the component W2 during application of ultrasonic vibration can be suppressed. Accordingly, inconvenience of misalignment of the component W2 is less likely to occur, and good joining quality can be obtained in joining using the joining material M. Note that, from the viewpoint of suppressing misalignment, the gas supplied to the holding holes 22 need not be inert gas, either (the same applies hereinafter). Note also that, by using inert gas as the gas, inconvenience of oxidation of the joining material M during joining is less likely to occur, and thereby good joining quality can be obtained.

In this embodiment, the plurality of holding holes 22 include first to Nth holding holes 22 (where N is an integer of two or more) aligned in the left-right direction. Further, the gas supply path 26 includes a gas flow path 26A extending in the left-right direction, and first to Nth communication paths 26B branching from the gas flow path 26A and respectively communicating with the first to Nth holding holes 22. With such a simple configuration, the inert gas can be caused to impinge on the component W2 from above. Note that the gas supply path 26 may have another structure.

Further, the gas flow path 26A has one end open at the side surface 25A of the lid 25 and the other end open at the side surface 25B of the lid 25 opposite to the side surface 25A, and the gas supply device 50 supplies the inert gas to the gas flow path 26A from the one end and the other end. The flow rate of the inert gas flowing through the first to Nth communication paths 26B decreases as a distance from a supply position of the inert gas in the gas flow path 26A increases. However, by supplying the inert gas to the gas flow path 26A from both ends thereof, a difference in the flow rate of the inert gas flowing through the first to Nth communication paths 26B can be reduced. As a result, variation in an amount of the inert gas supplied to each holding hole 22 is reduced, and inconvenience of oxidation of the joining material M during joining is less likely to occur.

As a modification of the above, as shown in FIG. 6, the plurality of holding holes 22 may include first to Mth holding holes 22 (where M is an integer of two or more) respectively arranged at a plurality of positions arranged in a matrix in plan view, and the gas supply path 26 may include a plurality of gas flow paths 26A extending in the left-right direction, a plurality of gas flow paths 26C extending in the front-back direction, and first to Mth communication paths 26B branching from at least some of intersections between the plurality of gas flow paths 26A and the plurality of gas flow paths 26C and respectively communicating with the first to Mth holding holes 22. The inert gas may be introduced from any position.

The heater 30 may be configured to heat the jig body 21 by induction heating. In such a case, the heater 30 includes a coil, and the power supply circuit 40 supplies a high-frequency current to the coil. The coil may be arranged not below the jig 20 but at a position surrounding the jig 20. In such a case, the coil and a stage supporting the jig 20 may be provided separately. The heater includes such a combination of the coil and the stage as well. In the case of induction heating, a magnetic material having high thermal conductivity, such as an Fe-Si alloy, Ni-coated steel, or carbon steel, may be employed as a material of the jig body 21. In induction heating, heat conduction through the jig body 21 tends to be more stable than direct heating of the workpieces W, and therefore inconvenience of non-uniform heating among the plurality of workpieces W (the same applies hereinafter to non-uniform heating) is less likely to occur, and thereby good joining quality can be obtained. Further, by heating the jig body 21 by induction heating, joining by induction heating becomes possible even when the component W1 or W2 of the workpiece W is made of a non-magnetic material such as metal, resin, or ceramic. More specifically, joining of materials that are difficult to heat by induction, such as aluminum, copper, stainless steel, and resin, becomes possible.

As a modification, positions of the holding holes 22 may be devised in order to improve heating efficiency for the workpieces W. For example, as shown in FIG. 7, the plurality of holding holes 22 may be respectively arranged only at some of a plurality of positions arranged in a matrix along the left-right direction and the front-back direction in plan view (in FIG. 7, eight positions excluding a central position) among a plurality of positions (3 × 3 = 9 positions at which the nine holding holes 22 of FIG. 2 are provided). In this manner, by filling some of the holding holes 22 of the above embodiment so that no holding holes 22 are provided there, a region R where no holding hole is provided can serve as a high-efficiency heat conduction region, and heat can be conducted to the holding holes around the region R. As a result, compared with a case where the holding holes 22 are arranged at all of the plurality of positions arranged in a matrix, a temperature difference among heating temperatures of the workpieces W in the respective holding holes 22 due to heating by the heater 30 can be reduced. In other words, the heating temperatures can be made closer to uniform, inconvenience of non-uniform heating can be made less likely to occur, and good joining quality can be obtained.

Further, in order to improve heating efficiency for the workpieces W, a distance in a predetermined direction between the holding holes 22 (a width of the partition wall 23) may be varied (for example, see distances D1 and D2 between the holding holes 22 aligned in the front-back direction in FIG. 8). As a result, by adjusting shapes of portions having good thermal conductivity and portions having poor thermal conductivity (generally, the holding holes 22) in the jig body 21, heating efficiency for the workpieces W can be improved. As a result, good joining quality can be obtained. Further, a portion having a longer distance also serves as

reinforcement. Therefore, by making a portion of the jig body 21 that is likely to warp due to heating correspond to the portion having the longer distance, deformation such as warping of the jig body 21 during heating is suppressed. Thus, the jig body 21 has a partitioned tray shape in which the plurality of holding holes 22 are respectively arranged at at least some of a plurality of positions arranged in a matrix in plan view. The plurality of holding holes 22 may include a first holding hole, a second holding hole different from the first holding hole, and a third holding hole different from the first holding hole and the second holding hole, the first holding hole, the second holding hole, and the third holding hole being aligned in a predetermined direction such as the front-back direction, and the jig body 21 may have a shape in which a distance between the adjacent first holding hole and second holding hole (for example, D1) is different from a distance between the adjacent second holding hole and third holding hole (for example, D2). As a result, compared with a case where the distances are equal, a temperature difference among heating temperatures of the workpieces W in the respective holding holes 22 due to heating by the heater 30 can be reduced. In other words, the heating temperatures can be made closer to uniform, and non-uniform heating is reduced. In addition,

reinforcement is provided at a portion where the distance is longer.

Various further modifications can be made to the above embodiment. For example, various configurations described in the above embodiment are optional and may be changed as appropriate. For example, the processor 92 need only be constituted by one or more IC chips. Examples of the IC chips include an ASIC (Application Specific Integrated Circuit) and an FPGA (Field-Programmable Gate Array). Programs need only be stored in a non-transitory computer-readable storage medium such as the nonvolatile storage 91.

During joining, ultrasonic vibration need not be applied. In this case, the jig 20 may be pressed downward during joining by a pressing member provided instead of the horn 82. The jig 20 need not include the gas supply path 26. That is, supply of gas to the holding holes 22 is not essential, either. The jig 20 may also be used in a joining system having a configuration other than that of the joining system 10. (Supplementary Notes)

Configurations taking the above-described embodiment and modifications as examples are additionally noted below. The supplementary configurations can be combined with one another.

### Supplementary Note 1

There is provided a joining system comprising:

a jig including:

a jig body including a plurality of holding holes each configured to hold a corresponding one of a plurality of workpieces, each of the plurality of workpieces including a first component, a second component disposed above the first component, and a joining material disposed between the first component and the second component; and

a lid configured to, when disposed on the jig body, cover the plurality of holding holes;

a heater configured to heat the jig such that each of the plurality of workpieces is heated to effect joining of the first component and the second component with the heated joining material; and

an ultrasonic vibration applying device configured to apply ultrasonic vibration to the jig during the joining, thereby applying the ultrasonic vibration to the workpieces via the jig.

### Supplementary Note 2

The joining system according to Supplementary Note 1, wherein

the heater is configured to support the jig body from below and to heat the jig body, and

the ultrasonic vibration applying device includes an ultrasonic transducer and an ultrasonic horn connected to the ultrasonic transducer, and is configured to apply the ultrasonic vibration to the lid with the ultrasonic horn pressed against the lid from above.

### Supplementary Note 3

The joining system according to Supplementary Note 1 or 2, further comprising

a gas supply device configured to supply gas to each of the holding holes during the joining,

wherein

the lid includes a gas supply path configured to cause the gas to impinge from above on the second component of each of the plurality of workpieces.

### Supplementary Note 4

The joining system according to Supplementary Note 3, wherein

the gas is an inert gas.

### Supplementary Note 5

The joining system according to Supplementary Note 3 or 4, wherein

the plurality of holding holes include first through Nth holding holes, where N is an integer of two or more, aligned in a left-right direction orthogonal to an up-down direction, and

the gas supply path includes a gas flow path extending in the left-right direction, and first through Nth communication paths branching from the gas flow path and respectively configured to communicate with the first through Nth holding holes.

### Supplementary Note 6

The joining system according to Supplementary Note 5, wherein

the gas flow path has one end open at a first side surface of the lid and another end open at a second side surface of the lid opposite to the first side surface, and

the gas supply device is configured to supply the gas to the gas flow path from the one end and the other end.

### Supplementary Note 7

The joining system according to any one of Supplementary Notes 3 to 6, wherein

the plurality of holding holes include first through Mth holding holes, where M is an integer of two or more, respectively arranged at a plurality of positions that are at least some of a plurality of positions arranged in a matrix in plan view, and

the gas supply path includes a plurality of first gas flow paths extending in the left-right direction, a plurality of second gas flow paths extending in a front-back direction, and first through Mth communication paths branching from at least some intersections between the plurality of first gas flow paths and the plurality of second gas flow paths and respectively configured to communicate with the first through Mth holding holes.

### Supplementary Note 8

The joining system according to any one of Supplementary Notes 1 to 7, wherein

the heater is configured to heat the jig body by induction heating.

### Supplementary Note 9

The joining system according to any one of Supplementary Notes 1 to 8, wherein

the plurality of holding holes are respectively arranged at some of a plurality of positions arranged in a matrix in plan view.

### Supplementary Note 10

The joining system according to any one of Supplementary Notes 1 to 9, wherein

the jig body has a partitioned tray shape in which the plurality of holding holes are respectively arranged at a plurality of positions that are at least some of a plurality of positions arranged in a matrix in plan view,

the plurality of holding holes include a first holding hole, a second holding hole different from the first holding hole, and a third holding hole different from the first holding hole and the second holding hole, the first holding hole, the second holding hole, and the third holding hole being aligned in a predetermined direction, and

the jig body has a shape in which a distance between the adjacent first holding hole and second holding hole is different from a distance between the adjacent second holding hole and third holding hole.

### Supplementary Note 11

There is provided a jig comprising:

a jig body including a plurality of holding holes each configured to hold a corresponding one of a plurality of workpieces, each of the plurality of workpieces including a first component, a second component disposed above the first component, and a joining material disposed between the first component and the second component; and

a lid configured to, when disposed on the jig body, cover the plurality of holding holes.

### Supplementary Note 12

The jig according to Supplementary Note 11, wherein

the lid includes a gas supply path configured to cause gas supplied from a gas supply device to impinge from above on the second component of each of the plurality of workpieces.

### Supplementary Note 13

The jig according to Supplementary Note 11 or 12, wherein

the plurality of holding holes are respectively arranged at some of a plurality of positions arranged in a matrix in plan view.

### Supplementary Note 14

The jig according to any one of Supplementary Notes 11 to 13, wherein

the jig body has a partitioned tray shape in which the plurality of holding holes are respectively arranged at a plurality of positions that are at least some of a plurality of positions arranged in a matrix in plan view,

the plurality of holding holes include a first holding hole, a second holding hole different from the first holding hole, and a third holding hole different from the first holding hole and the second holding hole, the first holding hole, the second holding hole, and the third holding hole being aligned in a predetermined direction, and

the jig body has a shape in which a distance between the adjacent first holding hole and second holding hole is different from a distance between the adjacent second holding hole and third holding hole.

### Supplementary Note 15

The joining system or the jig according to any one of Supplementary Notes 1 to 14, wherein

the joining material includes any one of a brazing material, solder, a sintering material, a thermoplastic resin, and a thermosetting resin.

### Scope of Present Disclosure

The present disclosure has been described above with reference to the embodiments and modifications. However, the present disclosure is not limited to the above-described embodiments and modifications. For example, the present disclosure includes various modifications to the above-described embodiments and modifications that can be understood by those skilled in the art within the technical concept of the present disclosure. The configurations described in the above-described embodiments and modifications may be combined as appropriate insofar as no inconsistency arises. Omission of any of the configurations is also optional.

### Incorporation by Reference

This application claims the benefit of Japanese Patent Application No. 2025-055587, filed on March 28, 2025, the entire disclosure of which is incorporated by reference herein.

### Explanation of the Reference Numerals and Signs

10...joining system, 20...jig, 21...jig body, 22...holding hole, 23...partition wall, 25...lid, 25A...side surface, 25B...side surface, 26...gas supply path, 26A...gas flow path, 26B...communication path, 26C...gas flow path, 30...heater, 40...power supply circuit, 50...gas supply device, 51...gas cylinder, 52...gas pipe, 53...flow control valve, 80...ultrasonic vibration applying device, 81...ultrasonic transducer, 82...ultrasonic horn, 83...drive device, 84...power supply circuit, 90...controller, 91...storage, 92...processor, 93...main memory, D1...distance, D2...distance, M...joining material, R...region, W...workpiece, W1...component, W2...component

1. A joining system comprising:
a jig including:
a jig body including a plurality of holding holes each configured to hold a corresponding one of a plurality of workpieces, each of the plurality of workpieces including a first component, a second component disposed above the first component, and a joining material disposed between the first component and the second component; and
a lid configured to, when disposed on the jig body, cover the plurality of holding holes;
a heater configured to heat the jig such that each of the plurality of workpieces is heated to effect joining of the first component and the second component with the heated joining material; and
an ultrasonic vibration applying device configured to apply ultrasonic vibration to the jig during the joining, thereby applying the ultrasonic vibration to the workpieces via the jig.

2. The joining system of claim 1, wherein
the heater is configured to support the jig body from below and to heat the jig body, and
the ultrasonic vibration applying device includes an ultrasonic transducer and an ultrasonic horn connected to the ultrasonic transducer, and is configured to apply the ultrasonic vibration to the lid with the ultrasonic horn pressed against the lid from above.

3. The joining system of claim 1, further comprising
a gas supply device configured to supply gas to each of the holding holes during the joining, wherein
the lid includes a gas supply path configured to cause the gas to impinge from above on the second component of each of the plurality of workpieces.

4. The joining system of claim 3, wherein
the gas is an inert gas.

5. The joining system of claim 3, wherein
the plurality of holding holes include first through Nth holding holes, where N is an integer of two or more, aligned in a left-right direction orthogonal to an up-down direction, and
the gas supply path includes a gas flow path extending in the left-right direction, and first through Nth communication paths branching from the gas flow path and respectively configured to communicate with the first through Nth holding holes.

6. The joining system of claim 5, wherein
the gas flow path has one end open at a first side surface of the lid and another end open at a second side surface of the lid opposite to the first side surface, and
the gas supply device is configured to supply the gas to the gas flow path from the one end and the other end.

7. The joining system of claim 3, wherein
the plurality of holding holes include first through Mth holding holes, where M is an integer of two or more, respectively arranged at a plurality of positions that are at least some of a plurality of positions arranged in a matrix in plan view, and
the gas supply path includes a plurality of first gas flow paths extending in the left-right direction, a plurality of second gas flow paths extending in a front-back direction, and first through Mth communication paths branching from at least some intersections between the plurality of first gas flow paths and the plurality of second gas flow paths and respectively configured to communicate with the first through Mth holding holes.

8. The joining system of claim 1, wherein
the heater is configured to heat the jig body by induction heating.

9. The joining system of claim 1, wherein
the plurality of holding holes are respectively arranged at some of a plurality of positions arranged in a matrix in plan view.

10. The joining system of claim 1, wherein
the jig body has a partitioned tray shape in which the plurality of holding holes are respectively arranged at a plurality of positions that are at least some of a plurality of positions arranged in a matrix in plan view,
the plurality of holding holes include a first holding hole, a second holding hole different from the first holding hole, and a third holding hole different from the first holding hole and the second holding hole, the first holding hole, the second holding hole, and the third holding hole being aligned in a predetermined direction, and
the jig body has a shape in which a distance between the first holding hole and the second holding hole adjacent thereto is different from a distance between the second holding hole and the third holding hole adjacent thereto.

11. The joining system of claim 1, wherein
the joining material includes any one of a brazing material, solder, a sintering material, a thermoplastic resin, and a thermosetting resin.

12. A jig comprising:
a jig body including a plurality of holding holes each configured to hold a corresponding one of a plurality of workpieces, each of the plurality of workpieces including a first component, a second component disposed above the first component, and a joining material disposed between the first component and the second component; and
a lid configured to, when disposed on the jig body, cover the plurality of holding holes.

13. The jig of claim 12, wherein
the lid includes a gas supply path configured to cause gas supplied from a gas supply device to impinge from above on the second component of each of the plurality of workpieces.

14. The jig of claim 12, wherein
the plurality of holding holes are respectively arranged at some of a plurality of positions arranged in a matrix in plan view.

15. The jig of claim 12, wherein
the jig body has a partitioned tray shape in which the plurality of holding holes are respectively arranged at a plurality of positions that are at least some of a plurality of positions arranged in a matrix in plan view,
the plurality of holding holes include a first holding hole, a second holding hole different from the first holding hole, and a third holding hole different from the first holding hole and the second holding hole, the first holding hole, the second holding hole, and the third holding hole being aligned in a predetermined direction, and
the jig body has a shape in which a distance between the first holding hole and the second holding hole adjacent thereto is different from a distance between the second holding hole and the third holding hole adjacent thereto.
